(19) United States
(12) Patent Application Publication
(10) Pub. No.: US 2005/0099774 A1
(43) Pub. Date: May 12, 2005

(54) Semiconductor chip cooling module with fin-fan-fin configuration

(76) Inventor: Kyu Sop Song, Daejeonsi (KR)

Correspondence Address: LADAS & PARRY, 5670 WILSHIRE BOULEVARD, SUITE 2100, LOS ANGELES, CA, 90036-5679, US

(21) Appl. No.: 10/704,187

(22) Filed: Nov. 6, 2003

(51) Int. Cl. H05K 7/20

(52) U.S. Cl. 361/700; 361/697

(57) ABSTRACT

The present invention relates to a semiconductor chip cooling module with fin-fan-fin configuration employing a heat pipe provided with air ventilating means having a forced convection cooling type radiating method of forcedly cooling heat radiating fins by ventilating a wind to rapidly discharge and cool heat generated from a central processing unit (hereinafter referred to as “CPU”) mounted on a main board of a computer; the present invention comprises a heat radiating plate having a plurality of slots, a pair of heat pipes installed in the slots in a symmetrical relationship, and air ventilating means having a ventilating fan installed between heat radiating pins of the pair of heat pipes, wherein an air is ventilated to the heat radiating pins to forcedly radiate the heat radiating pins. The present invention is capable of embodying a rapid radiation on an overheat of the CPU by employing a forced direct cooling method that air ventilating means is installed at a center of plural rows of heat pipes to ventilate an air to thereby forcedly and directly cool the heat radiating fins mounted on the plural rows of heat pipes.

### TECHNICAL FIELD

The present invention relates to a semiconductor chip cooling module with fin-fan-fin configuration employing a heat pipe, and more particularly to a semiconductor chip cooling module with fin-fan-fin configuration employing a heat pipe provided with air ventilating means having a heat radiating function of a forced convection cooling type for forcedly cooling heat radiating fins by ventilating a wind in order to promptly discharge and cool heat generated from a central processing unit (hereinafter referred to as “CPU”) mounted on a main board of a computer.

### BACKGROUND ART

Generally, as the current society rapidly advances to an information society, a computer capable of calculating (processing) a large quantity of information and data is required; therefore, a CPU capable of rapidly processing a large quantity of data has been developed to satisfy desires of those consumers.

As described above, since the CPU generates a large quantity of heat during a data processing, when the heat generated from the CPU itself is risen up to a predetermined temperature, the heat affects a harmful influence to a system operation, thereby generating a system error.

To prevent this error from occurring, the heat generated from the CPU should be promptly discharged to be maintained with a predetermined temperature, i.e., below 50 to 60° C.; when the temperature is risen up to above 100° C., since the system operation becomes unstable to generate a malfunction phenomenon, the heat is forcedly discharged from the CPU to make the CPU accomplish a normal function.

A prior art cooling apparatus for forcedly cooling the heat generated from the CPU uses an ultra thermal conductor cooling apparatus employing a heat pipe as shown in FIG. 1. The ultra thermal conductor cooling apparatus employing the prior heat pipe as shown in FIG. 1 is provided with a mount 10 soldered on a printed circuit board (not shown), a CPU 20 installed at the mount 10, and a heat radiating plate 30 attached to be surface contacted with a surface of the CPU 20.

The heat radiating plate 30 has a slot 31 formed on its flat surface, and a heat pipe 32 is engaged within the slot 31. The heat pipe 32 is bended upward to be attached such that heat-radiating fins 33 are overlapped.

The heat pipe 32 functions as an intermediation for transmitting the heat transmitted from the heat radiating plate 30 to the heat radiating fins 33, i.e., functions as an intermediation for accomplishing a heat transfer by means of a phase change of a working fluid by filling the working fluid in an inner portion of low pressure to make a heat transfer speed very fast.

Therefore, the heat generated from the CPU 20 is transferred to the heat pipe 32 through the heat radiating plate 30, and the heat conducted to the heat pipe 32 is transferred to the heat radiating fins 33 to irradiate the heat of the CPU 20.

However, since the heat radiating apparatus using the prior art heat pipe 32 employs a forced convection method that the heat generated from the CPU 20 is radiated through one row of heat pipe as an intermediate, when the CPU accomplishes a large quantity of calculating function at a time, the CPU 20 generates a rapid overheat phenomenon due to an overload, but the corresponding rapid radiation does not accomplished.

Since a substantial time of heat transfer from the heat radiating plate 30 via the heat pipe 32 to the heat radiating fins 33 is required, the rapid radiation should be limited; when the heat generated from the CPU 20 becomes excessively high, the configuration of the one low of heat radiating fins 33 has a problem of providing an inefficient cooling effect of the CPU 20.

Therefore, in the prior art radiating apparatus, the problem of malfunction of a computer has been often occurred due to an erroneous operation of the CPU having a limitation in counter measure corresponding to a rapid overheat.

### DISCLOSURE OF INVENTION

To solve the above-mentioned problems, an object of the present invention is to provide a semiconductor chip cooling module with fin-fan-fin configuration capable of cooling a CPU through an effective cooling of a heat radiating plate in contact with the CPU by forming a plural rows of heat pipes about the heat radiating plate and forming heat radiating fins on a condensing part to effectively cool the excessive heat of the CPU.

Another objects of the present invention is to provide a semiconductor chip cooling module with fin-fan-fin configuration capable of providing a maximum stability of a CPU performance by means of employing a direct forced radiating method that a wind is forcedly ventilated between heat radiating fins formed in a condensing part of a plural rows of heat pipes to more rapidly discharge heat of the heat pipes.

The fin-fan-fin configuration means the configuration that a fan for supplying a cooling air is located between the heat radiating fins of the plural rows of heat pipes.

A considerable point for solving the above-mentioned problems in the present invention is that a radiation effect is artificially and forcedly adjustable.

These objects of the present invention is accomplished by means of forming a plurality of slots on a heat radiating plate to attach a pair of heat pipes, at which heat radiating fins are attached, in a symmetrical relationship to the slots each other, and installing air ventilating means having a ventilating fan between the heat radiating fins attached at the pair of heat pipes to ventilate an air to the heat radiating fins to forcedly radiate heat.

A first embodiment of the air ventilating means of the present invention may employ an axial flow fan, and a second embodiment may employ a bi-directional air intake centrifugal fan.

While the air ventilating means in accordance with the first and the second embodiments will be more specifically described, the axial flow fan in accordance with the first embodiment is installed between the both sides of heat radiating fins to allow air introduction through one side of the heat radiating fins and to allow a discharge of the introduced air to the other side of heat radiating fins;

the bi-directional air intake centrifugal fan in accordance with the second embodiment is capable of timely and artificially improving a radiating efficiency of heat radiating fins by means of a centrifugal fan operated to discharge upward an air entered from an exterior part to an interior part of the both sides of the heat radiating fins.

### BRIEF DESCRIPTION OF THE DRAWINGS

These and other features, aspects, and advantages of preferred embodiments of the present invention will be more fully described in the following detailed description, taken accompanying drawings. In the drawings:

FIG. 1 is an exemplary perspective view of an ultra thermal conductor radiating apparatus employing a prior art heat pipe;

FIG. 2 is an exemplary perspective view of a semiconductor chip cooling module with a fin-fan-fin configuration in accordance with the present invention;

FIG. 3a is an exemplary perspective view of an example employing an axial flow fan as a first embodiment of air ventilating means in accordance with the present invention;

FIG. 3b is an exemplary perspective view of an example employing a bi-directional air intake centrifugal fan as a second embodiment of air ventilating means in accordance with the present invention;

FIG. 4a is a longitudinal cross-sectional view of the first embodiment shown in FIG. 3a;

FIG. 4b is a longitudinal cross-sectional view of the second embodiment shown in FIG. 3b; and

FIG. 5 is an exemplary longitudinal cross-sectional view of a modified example of a semiconductor chip cooling module with fin-fan-fin configuration in accordance with the present invention.

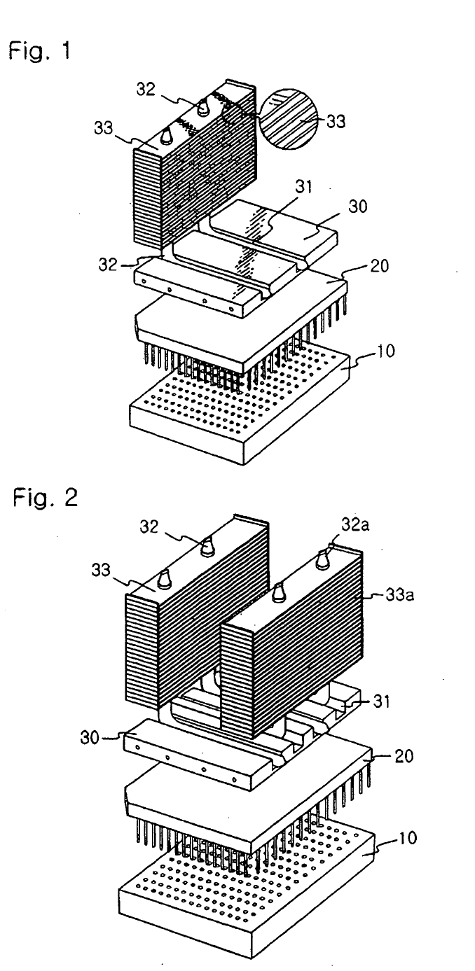

### BEST MODES FOR CARRYING OUT THE INVENTION

Hereinafter, a semiconductor chip cooling module with fin-fan-fin configuration in accordance with the present invention will be apparent from the detailed description in conjunction with the accompanying drawings.

Referring to FIG. 2, FIG. 2 is an exemplary perspective view of a semiconductor chip cooling module with a fin-fan-fin configuration in accordance with the present invention.

While the same components as those of the prior art among reference numerals shown in the drawings are designated with the same reference numerals, components consisted of one pair are discriminated by adding an alphabet after the reference numerals, and a description of the same components of the present invention as the described prior art components will be omitted.

As it aware from the drawings, reference numeral 30 is a heat radiating plate in surface contact with a CPU 20. The heat radiating plate 30 is provided with a slot 31 in which a pair of heat pipes 32 and 32a installed through between the numerous heat radiating fins 33 and 33a are bended and inserted. The pair rows of heat pipes 32 and 32a are installed to face to face with each other. Peripheral surfaces of the heat pipes 32 and 32a are provided with the numerous heat radiating fins 33 and 33a folded to be overlapped with each other to discharge heat to exterior.

An air ventilating means 40 is installed between the pair of heat radiating fins 33 and 33a.

The air ventilating means 40 of the present invention make a wind pass through between the heat radiating fins 33 and 33a to forcedly cool the heat radiating fins 33 and 33a; at least two types can be employed. A first type is the way that, in entering an air from exterior to between the both sides of the heat radiating plate, the air is entered to the one side of the heat radiating fin 33 and the entered air is discharged to the other side of the heat radiating fin 33a; a second type is the way that the air entered from exterior coincidently pass through between the both sides of the heat radiating fins 33 and 33a to be discharged upward.

The first embodiment of the air ventilating means will be described.

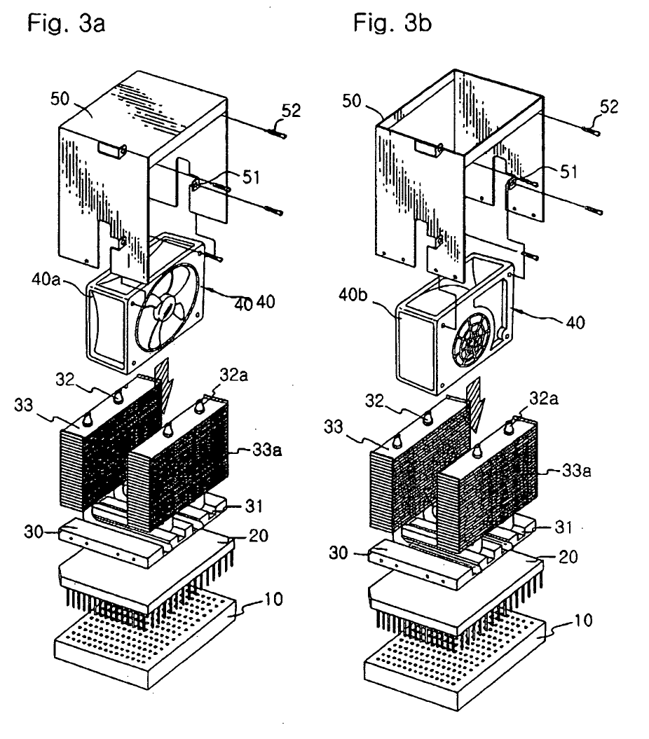

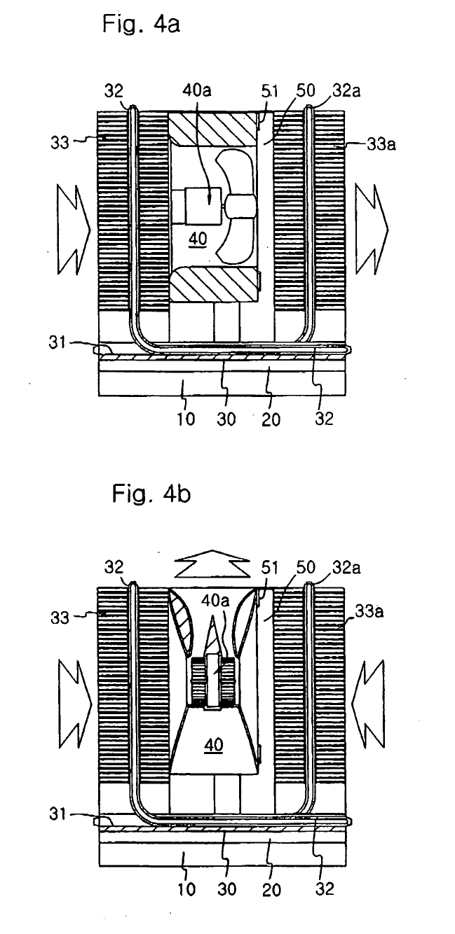

Referring to FIGS. 3a and 4a, FIG. 3a is an exemplary perspective view of an example employing an axial flow fan as an air ventilating means in accordance with a first embodiment of the present invention, and FIG. 4a is a longitudinal cross-sectional view of the first embodiment shown in FIG. 3a.

As shown in FIG. 3a, the axial flow fan 40a is installed between the both of heat radiating fins 33 and 33a, and when the axial flow fan 40a is rotated, the air is entered to the one side of the heat radiating fins 33 and discharged to the other side of the heat radiating fins 33a; at this time, the wind passes through between the pair of heat radiating fins 33 and 33a by the axial flow fan 40a to cool the heat of the heat radiating fins 33 and 33a.

The second embodiment of the air ventilating means 40 will be described.

Referring to FIGS. 3b and 4b, FIG. 3b is an exemplary perspective view of an example employing a bi-directional air intake centrifugal fan as an air ventilating means in accordance with a second embodiment of the present invention; and FIG. 4b is a longitudinal cross-sectional view of the second embodiment shown in FIG. 3b.

As shown in FIG. 3b, the bi-directional air intake centrifugal fan 40b is installed at a space between the both heat radiating fins 33 and 33a, and the bi-directional air intake centrifugal fan 40b introduce the air to between the both heat radiating fins 33 and 33a to discharge the air upward, thereby cooling the heat radiating fins 33 and 33a by means of the air entered between the heat radiating fins 33 and 33a.

As described above, a cooling operation of the heat radiating fins 33 and 33a by the air ventilating means 40 located between the plural rows of heat pipes, since a radiating effect of the forced air cooling method has more effective cooling effect of the CPU than the one row of heat pipe configuration attached to the heat radiating plate, the forced air cooling method is capable of rapidly radiating though a rapid overheat of the CPU 20 due to an excellent radiating ability in comparison with the prior art one row heat pipe configuration.

In the drawings, reference numeral 50 designates a casing for fixing the air ventilating means 40, which the axial flow fan and the centrifugal fan are fastened through a screw 52 to a bracket 51 internally bended.

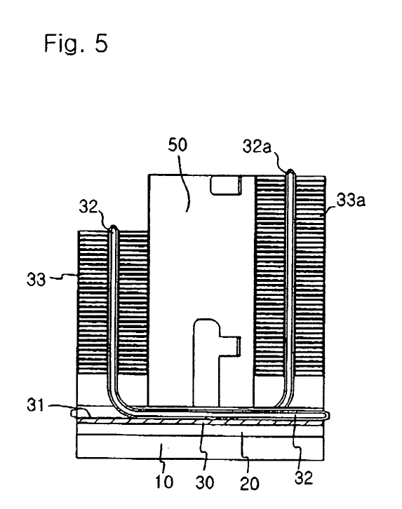

Referring to FIG. 5, FIG. 5 is an exemplary longitudinal cross-sectional view of a modified example of a semiconductor chip cooling module with fin-fan-fin configuration in accordance with the present invention, when the axial flow fan is mounted.

This is a modified example that the radiation effect is improved by varying the number of the heat radiating fins attached to each of the heat pipe 32 and 32a.

As it aware from FIG. 5, the number of heat radiating fins per inch of the one side is less than the number of heat radiating fins of the other side with reference to the number of heat radiating fins per inch FPI; or a height of heat radiating fins attached on the heat pipe is different from each other.

If the numbers of the both sides of heat radiating fins are same, or the heights of the heat radiating fins attached on the both sides of condensing part become same, when the air passed through between the heat radiating fins attached on the one side of the heat pipe is heat exchanged with the condensing part in the heat pipe to pass through between the other side of heat radiating fins, since there is no temperature differential in comparison with the other side of heat radiating fins, a thermal efficiency of the heat radiating fins may be decreased.

Therefore, in order to provide an even thermal efficiency of the one side and the other side of heat radiating fins, the number of the one side and the other side of heat radiating fins is arranged to be different from each other.

Further, since the number of the one side of heat radiating fins becomes less than the other side, an effect of reducing an air resistance is provided.

As described hereinabove, a semiconductor chip cooling module with a fin-fan-fin configuration in accordance with the present invention is capable of preventing a CPU performance from lowering by accomplishing a rapid radiation in spite of a rapid overheat of the CPU since a wind is directly ventilated to a plural rows of heat radiating fins to show an outstanding radiating performance in comparison with one low of heat radiating fins.

Therefore, though a radiating apparatus employing a prior art heat pipe accomplishes a cooling of a CPU through the medium of one row of heat pipe, the present invention is capable of embodying a rapid radiation on an overheat of the CPU by means of employing a forced cooling method that air ventilating means is installed at a center of plural rows of heat pipes to ventilate an air to thereby forcedly cool the heat radiating fins.

While this invention has been described in connection with what is presently considered to be the most practical and preferred embodiment, it is to be understood that the invention is not limited to the disclosed embodiment, but on the contrary, it is intended to cover various modification within the spirit and scope of the appended claims.

1. A semiconductor chip cooling module with fin-fan-fin configuration employing a heat pipe, characterized in that a heat radiating plate 30 for cooling a CPU 20 is attached to be surface contacted with a surface of the CPU 20, plural rows of heat pipes 32 is formed to radiate a heat transferred to the heat radiating plate 30, heat radiating fins 33 and 33a are over layered to each heat pipe to radiate a heat on a condensing part of the plural rows of heat pipe 32, and air ventilating means 40 are installed between each of heat radiating fins 33 and 33a of the plural rows of heat pipes.

2. The semiconductor chip cooling module according to claim 1, characterized in that the air ventilating means 40 is an axial flow fan, and the air is entered to the one side of heat radiating fins 33 and discharged to the other side of heat radiating fins 33a.

3. The semiconductor chip cooling module according to claim 1, characterized in that the air ventilating means 40 employ a bi-directional air intake centrifugal fan 40b to enter an air in a pair of heat radiating fins 33 and 33a coincidently to discharge the air upward, thereby directly cooling the both of heat radiating fins 33 and 33a by means of the air entered between the heat radiating fins.

4. The semiconductor chip cooling module according to claim 1, characterized in that the number of the heat radiating fins attached at the pair of heat pipes is different from each other with a reference to the number of heat radiating fins per inch.
